(19) United States
(12) Patent Application Publication
(10) Pub. No.: US 2002/0089354 A1
(43) Pub. Date: Jul. 11, 2002

(54) Apparatus and method of providing a four input logic function

(76) Inventors: Ikuo Jimmy Sanwo, San Marcos, CA (US); Mahyar Nejat, San Diego, CA (US); Jean-Robert Clerge, Phoenix, AZ (US)

Correspondence Address: Sony Electronics Inc., Intellectual Property Depart, 16450 WEST BERNARDO DRIVE, MZ7190, SAN DIEGO, CA, 92127-1898, US

(21) Appl. No.: 09/755,854

(22) Filed: Jan. 8, 2001

(51) Int. Cl. H03K 19/094

(52) U.S. Cl. 326/121

(57) ABSTRACT

The present invention is a method and apparatus for providing a four input logic function. The apparatus comprises: a coupling circuit; a first circuit having at least a first input terminal for receiving a first input signal and a second input terminal for receiving a second input signal wherein the first circuit uses the coupling circuit for coupling the first and second input signals so as to generate an output signal wherein the output signal being a logic relationship between the first and second input signals; a second circuit having at least a third input terminal for receiving a third input signal and a fourth input terminal for receiving a fourth input signal wherein the second circuit uses the coupling circuit for coupling the third and fourth input signals so as to generate an output signal wherein the output signal being a logic relationship between the third and fourth input signals; and a third circuit using the coupling circuit for coupling the first and second circuits wherein the third circuit generates a first output signal and a second output signal having a logic relationship between the first, second, third and fourth inputs signals wherein the first output signal being at a first output state and the second output signal being at a second output state.

### BACKGROUND OF THE INVENTION

1. Field of invention

The present invention relates generally to integrated circuits, and more particularly to a method and apparatus of providing a logic function for a commonly used four input circuit having both an exclusive OR and exclusive NOR logic kind of signals outputted therefrom.

2. Description of the Related Art

An integrated circuit (IC) of four inputs coupled with an exclusive OR and exclusive NOR logic circuit are commonly used in a multitude of VLSI CMOS computers and/or digital television circuits. Moreover, such four input exclusive OR and exclusive NOR logic functions are the fundamental components used in the development of such devices. Furthermore, the four input exclusive OR and exclusive NOR functions are found in a variety of usages which include error detection, error correction, and parity control.

A related implementation shown in FIG. 1 of the four input exclusive OR and exclusive NOR function circuit consists of utilizing twenty six transistors. In this circuit, four inputs A, B, C, D are coupled in pairs of two inputs to two separate driver circuits. Each of the driver circuits requires eight transistors, and each of the driver circuits are subsequently coupled to a third circuit requiring ten transistors. Hence, this circuit design requires an inordinate number of transistors which in turn requires a large amount of silicon in the overall execution of the four input exclusive OR and exclusive NOR gate structure. The resulting circuit structure has other drawbacks because of the coordinate number of transistors, these include decreases in chip performance, increases in manufacturing costs, decreases in the reliability of the circuit and other problems associated therewith.

Accordingly, there is a need in the technology for a versatile easy to implement circuit with four inputs coupled to an exclusive OR and exclusive NOR output gates without the above mentioned drawbacks. Such a circuit would also enable the chip user, chip manufacture, and chip designer to reduce other negative effects associated with the circuit which include increases in extraneous noise, power consumption and manufacturing costs while being able to maintain consistent or higher performance.

### BRIEF SUMMARY OF THE INVENTION

The present invention is a method and apparatus for providing an integrated circuit of a four inputs having an exclusive OR and exclusive NOR output configuration.

The apparatus provides for a logic function having: a coupling circuit; a first circuit having at least a first input terminal for receiving a first input signal and a second input terminal for receiving a second input signal wherein said first circuit uses said coupling circuit for coupling said first and second input signals so as to generate an output signal wherein the output signal being a logic relationship between the first and second input signals; a second circuit having at least a third input terminal for receiving a third input signal and a fourth input terminal for receiving a fourth input signal wherein said second circuit uses said coupling circuit for coupling said third and fourth input signals so as to generate an output signal wherein the output signal being a logic relationship between the third and fourth input signals; and a third circuit using said coupling circuit for coupling the first and second circuits wherein said third circuit generates a first output signal and a second output signal having a logic relationship between the first, second, third and fourth inputs signals wherein the first output signal being at a first output state and said second output signal being at a second output state.

The apparatus further provides for a logic function comprising: a coupling circuit; a first circuit having at least a first input terminal for receiving a first input signal and a second input terminal for receiving a second input signal wherein said first circuit uses said coupling circuit for coupling said first and second input signals so as to generate an output signal wherein the output signal being a logic relationship between the first and second input signals; a second circuit having at least a third input terminal for receiving a third input signal and a fourth input terminal for receiving a fourth input signal wherein said second circuit uses said coupling circuit for coupling said third and fourth input signals so as to generate an output signal wherein the output signal being a logic relationship between the third and fourth input signals; and a third circuit using said coupling circuit for coupling the first and second circuits wherein said third circuit generates a first output signal and a second output signal having a logic relationship between the first, second, third and fourth inputs signals wherein the first output signal being at an ORing output logic state and said second output signal being a NORing output state

The above and other objects and features of the present invention will become more apparent from the following detailed description and the appended claims with reference to the accompanying drawings.

### BRIEF DESCRIPTION OF THE DRAWINGS

The present invention is illustrated by way of example but not limited to the figures of the accompanying drawings, in which like references indicate similar elements and in which:

FIG. 1 is a related schematic diagram illustrating an integrated circuit.

FIG. 2 is a detailed schematic diagram illustrating an integrated circuit according to an embodiment of the present invention.

FIG. 3 is a table illustrating logic states according to an embodiment of the present invention.

FIG. 4 is a table illustrating logic states according to an embodiment of the present invention

FIGS. 5a, 5b are timing diagrams according to an embodiment of the present invention.

### DETAILED DESCRIPTION OF THE PRESENT INVENTION

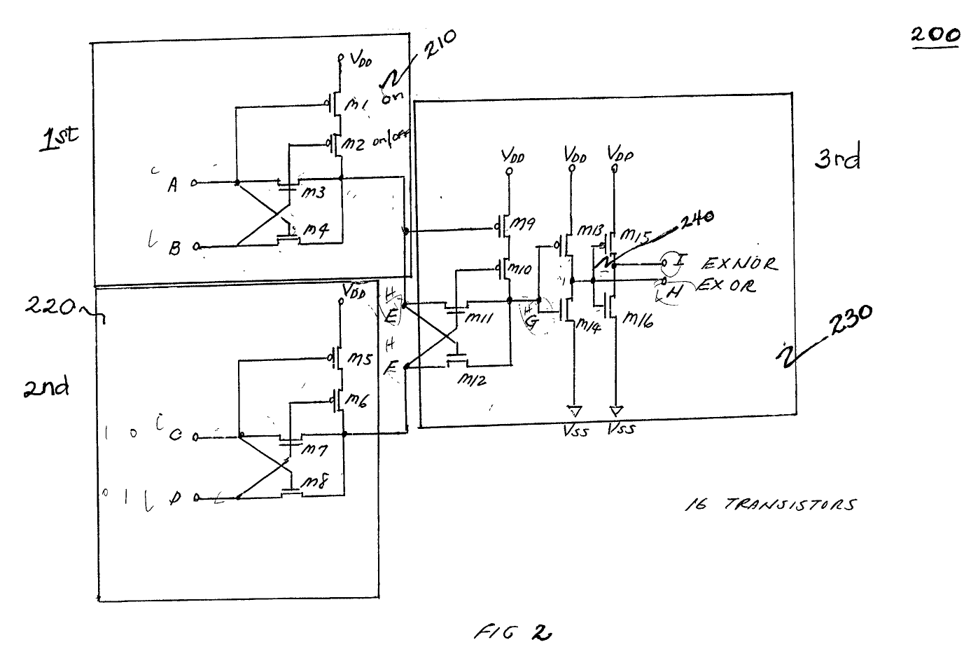

FIG. 2. is a block diagram illustrating an integrated circuit (IC) having four inputs, 16 transistors M1-M16 and an exclusive OR and an exclusive NOR output in accordance with principles of the present invention. As shown, the integrated circuit 200 has a set of driving circuits 210, 220 and an output circuit 230. The driving circuit 210 consists of inputs A and B and transistors M1, M2, M3, and M4. Input A is coupled to the gate of transistor M4 and M1, respectively and to the source of transistor M3. The source of transistor M1 is coupled to the constant voltage VDD. Transistors M1 and M2 are PMOS transistors, while transistors M3 and M4 are NMOS transistors. The drains of transistors M2, M3, and M4 are coupled together and the source of transistor M2 is coupled to the drain of transistor M1. Input B is coupled to the source of transistor M4 and the gates of transistors M3 and M2, while the drains of transistors M2, M3 and M4 are coupled to the node E. The driver circuit 220 is complementary to the driver circuit 210. The driving circuit 220 consists of inputs C and D, and of transistors M5, M6, M7, and M8. Input C is coupled to the gate of transistor M5 and M8, respectively and to the source of transistor M7. The source of transistor M5 is coupled to the constant voltage VDD and transistors M5 and M6 are PMOS transistors, while transistors M7 and M8 are NMOS transistors. The drains of transistors M6, M7, and M8 are coupled together while the source of transistor M6 is coupled to the drain of transistor M5. Input D is coupled to the source of transistor M8 and the gates of transistors M6 and M7, and the drains of transistors M6, M7 and M8 are coupled to the node F.

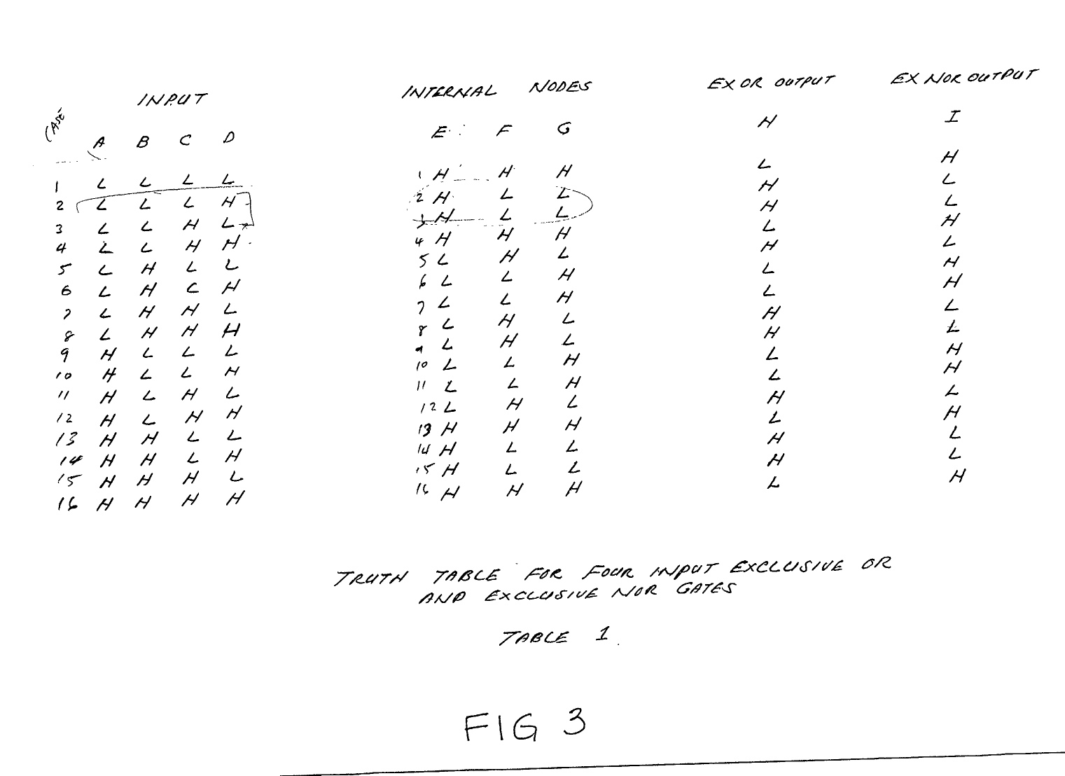

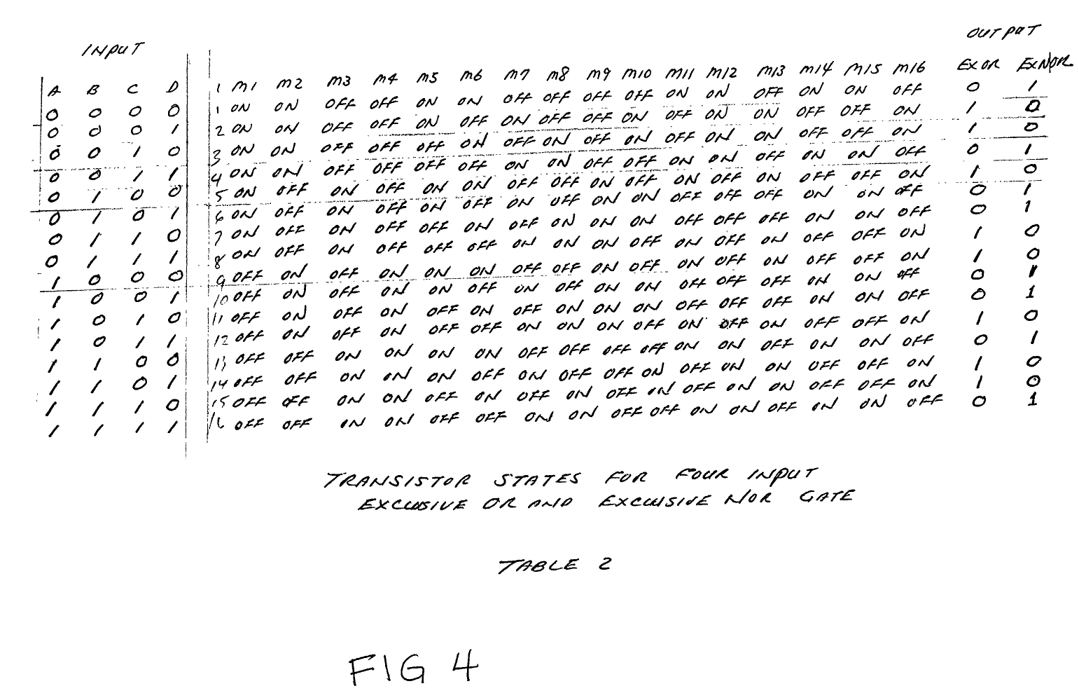

Output circuit 230 is coupled to the driver circuits 210, 220 via nodes E and F. The output driver operates in a number of logic states which correspond to the logic states in FIG. 3. For example, the states of the output components of the output driver 230 are associated with the four logic states in columns H and I of table 1 of FIG. 3, and the logic states in the columns in the EX OR and EX NOR of table 2 of FIG. 4. The output circuit consists of nodes E and F and transistors M9-M16. As shown, transistors M9, M10, M13, and M15 are PMOS transistors while transistors M11, M12, M14, and M16 are NMOS transistors. The gate of M9 is coupled to the output of driving circuit 210. Likewise the gate of transistor M10 is coupled to the output of driver circuit 220. The sources of transistors M9, M13 and M15 are each coupled to a separate source VDD. The drain of transistor M9 is coupled to the source of transistor M10. The gates of the two pairs of transistors M13, M14 and M15, M16 are each coupled together and the drains of transistors M14 and M15 are connected to separate potentials VSS. Further, the node E is connected to the gate of transistor M12 and the node F is connected to the gates of transistors M11 and M10. Output H is connected at the midpoint of the coupling of the drain of transistor M13 and the source of transistor M14. Output H is further connected to the coupling of the gates of transistors M15 and M16. While the output I is connected to the coupling of the drain of transistor M15 and source of transistor M16.

With reference to FIGS. 3 and 4, operation of the input driver circuit and the output driver circuit will now be described. The input signals A, B, C, and D each transition between at least two states, a state preferably corresponding to a logical low and a state preferably corresponding to a logical high.

With reference to driver circuit 210, the signal asserted at input A controls the transistors M1 and M4 between an ON state and an OFF state, while the signal asserted at input B controls the transistors M2 and M3 between an ON state and an OFF state. When both inputs A and B are each asserted with opposite logic signals, with input A at a logic high and input B at a logic low, the transistors M1 and M4 which are each coupled to input A are switched in the alternate with transistor M1 being turned OFF and transistor M4 being turned ON. Likewise, both transistors M2 and M3 which are coupled to input B are also controlled in the alternate with transistor M2 being switched ON and transistor M3 being switched OFF. The resulting voltage at node E is pulled down to a logic low as the flow from the supply Vdd to node E is cut-off with the transistor M1 OFF.

When the signal asserted at input A is a logic low and the signal asserted at input B is a logic high, the transistor M2 is switched OFF driving down the voltage at node E to a logic low. Only when both inputs A and B have signals asserted at logic highs or signals asserted at logic lows is the resulting voltage at node A, a logic high. Similarly, with signals asserted at logic lows for both inputs A and B, both transistors M1 and M2 are turned ON pulling of the resulting output to a logic high (Vdd). On the other hand, when both inputs signals A and B are logic highs, both transistors M3 and M4 are turned ON pulling up the voltage at node E to a logic high. With reference to driver circuit 220, when the signals asserted at inputs C and D are both high or both low then the resulting voltage at node F is at a logic high. As explained above in conjunction with driver circuit 210, and now with respect to driver circuit 220 the flow from source Vdd to node F is controlled by transistors M5 and M6. Hence, when both transistors M5 and M6 are turned ON by logic low signals asserted at inputs C and D, the node F is pulled up to a logic high by the source Vdd. When signals asserted at both inputs C and D are at a logic high, both transistors M7 and M8 are ON causing a similar result of having the voltage at node F pulled up to a logic high.

With reference to output circuit 200, and in particular transistors M9-M11, the signals asserted at nodes E and F and output at node G operate in the manner as described with respect to driver circuits 210 and 220. When the signals at nodes E and F of output circuit 200 are both at a logic high or at a logic low, the output at node G is at a logic high. When the signals at nodes E and F are in opposite states, node E being a logic high and node F being a logic low then the output at node G is at a logic low. Similarly, when node E is at a logic low and node F is at a logic high then the output at node G is at a logic low.

With reference to transistors M13-M16, when node G is at a logic low; the transistor M13 is ON, the transistor M14 is OFF, and the output H, the EX OR output, is pulled up to a logic high by source Vdd. Conversely, when node G is at a logic low, the output H is at a logic low as transistor M13 is OFF and transistor M14 is ON this pulls down the output H to a low voltage of Vss. Similarly, when the signal at node G is at a logic high, the input to the connector (240) of transistors M15 and M16 is at a logic low, transistor M15 is ON pulling up the output I, the EX NOR output, to Vdd or a logic high. Oppositely, when the signal at node G is at a logic low, the input to the connector (240) of transistors M15 and M16 is at a logic high, transistor M15 is OFF as is transistor M16 pulling down the H output to a low voltage of Vss.

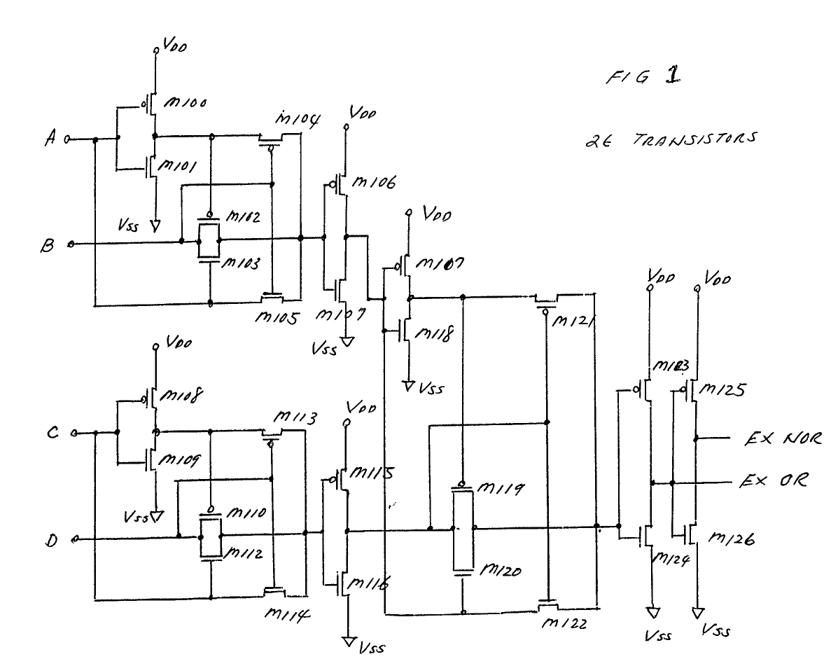

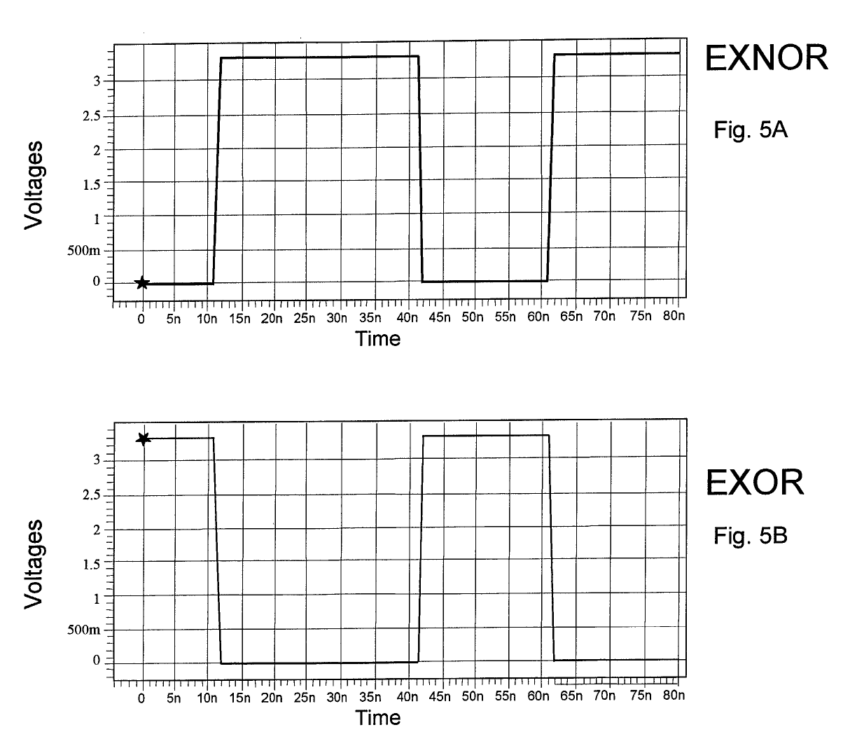

With reference to FIGS. 5a and 5b, an example of the operation of the logic circuit of FIG. 1 will now be explained.

FIGS. 5a and 5b show a timing chart of two states of the input signals. In the first state, the inputs A, B, C, D are asserted as follows with input A as a logic high, and inputs B, C, and D as logic lows. Input A actuates transistors M1 to the ON position, and inputs B, C, and D actuate transistors M2, M3 and M4 to the OFF position. Further, transistors M7 and M8 are switched OFF and transistors M5 and M6 are switched ON. As a result of which, transistors M5 and M6 are turned ON and node F is pulled up to voltage Vdd or a logic high.

Since switches M1 to M4 are OFF, the voltage at node E is held low. As both transistors M9 and M10 are coupled to node E, and transistor M9 is an NMOS transistor while transistor M12 is a PMOS transistor, the transistors are inversely actuated with transistor M9 turned ON and transistor M12 turned OFF. Similarly, at node F there are two transistors coupled in an inverse relationship with transistor M11 being a PMOS transistor and transistor M10 being an NMOS transistor. Since the signal asserted at node F is at a logic high, the transistor M11 is turned ON and inversely the transistor M10 is turned OFF. Node G connected to the output of transistors M1, M11, and M12 is pulled down by the voltage at node E, since transistors M10 and M12 are in an OFF state. Both transistors M13 and M14 are connected to node G where both transistors are also in an inverse relationship. The NMOS transistor M13 is turned ON by a low signal at node G and the PMOS transistor M14 is turned OFF. The output is coupled to both transistors M13 and M14, as a result of transistor M13 being turned ON, the voltage is pulled up to Vdd and so is the EX OR output. Similarly, the I output is pulled down to Vss as transistor M16 is turned ON and transistor M15 is turned OFF. Both these transistors M14 and M16 are coupled to the output of the transistors M13 and M14 and since the output of these transistors is high so too is the actuating signal to transistors M13 and M14.

From FIG. 5a the output from EXOR is kept high from 0 to 12 ns and the output from EX NOR is kept low from 0 to 12 ns. At 12 ns the signals asserted at inputs C and D are switched to C being a logic high and D also being a logic high. The signals at inputs A and B are unchanged. As a result, the transistors M5 and M8 connected to input C are switched to transistor MS being turned OFF and transistor M8 being turned ON and the transistors M6 and M7 connected to input D are also switched with transistor M7 being turned ON and transistor M6 being turned OFF. The resulting voltage at node F is changed to a low voltage. Since node F is connected to a NMOS transistor M10, transistor M10 is turned ON. Transistor M9 remains ON as the signal at node E remains unchanged. The voltage at node G is pulled up to Vdd since both transistors M9 and M10 are now ON. Hence the signal at node G is changed from a logic low to a logic high. Transistors M13 and M14 coupled to node G are asserted with a logic high signal pulling the output at H EXOR to a logic low. Transistor M14 is turned ON drawing down the voltage to Vss while transistor M13 is turned OFF. In contrast, EX NOR is switched to a logic high as transistor M15 is turned ON pulling the voltage up to Vdd. The H output is connected to transistor M14, so a low signal output from H would turn on the PMOS transistor M15. The EX NOR output is high for the rest of the time period 12 ns-42 ns.

The present invention thus provides an apparatus and method of providing four input signals outputting an NOR/OR logic output by using a layout of CMOS and PMOS transistors connected in a simplified manner permitting the designer to reduce power consumption without lessening performance.

The present invention may be embodied in other specific forms without departing from its spirit or essential characteristics. The described embodiments are to be considered in all respects only as illustrative and not restrictive. The scope of the invention is, therefore, indicated by the appended claims rather than the foregoing description. All changes which come within the meaning and range of equivalency of the claims are to embraced with their scope.

What is claimed is:

1. An apparatus for providing a logic function comprising:
a coupling circuit;
a first circuit having a first input terminal for receiving a first input signal and a second input terminal for receiving a second input signal wherein said first circuit uses said coupling circuit for coupling said first and second input signals so as to generate an output signal wherein the output signal being a logic relationship between the first and second input signals;
a second circuit having a third input terminal for receiving a third input signal and a fourth input terminal for receiving a fourth input signal wherein said second circuit uses said coupling circuit for coupling said third and fourth input signals so as to generate an output signal wherein the output signal being a logic relationship between the third and fourth input signals; and
a third circuit using said coupling circuit for coupling the first and second circuits wherein said third circuit generates a first output signal and a second output signal having a logic relationship between the first, second, third and fourth inputs signals wherein the first output signal being at a first output state and said second output signal being at a second output state.

2. The apparatus according to claim 1, wherein said first output state is a logic low.

3. The apparatus according to claim 1, wherein said second output state is a logic high.

4. The apparatus according to claim 1, wherein said coupling circuit includes a PMOS transistor having a source coupled to the first input terminal and a gate coupled to the second input terminal.

5. The apparatus according to claim 1, wherein said coupling circuit includes a PMOS transistor having a source coupled to the second input terminal and a gate coupled to the first input terminal.

6. The apparatus according to claim 1, wherein said coupling circuit includes a first PMOS transistor serially coupled to a second PMOS transistor having a gate of said first PMOS transistor coupled to a first input terminal and a gate of the second PMOS transistor coupled to a second input terminal.

7. The apparatus according to claim 1, wherein said coupling circuit includes a NMOS transistor having a source coupled to a first input terminal and a gate coupled to a second input terminal and a PMOS transistor having the source coupled to a second input terminal and the gate coupled to the first input terminal.

8. The apparatus according to claim 1, wherein said coupling circuit includes a first PMOS transistor coupled to a first NMOS transistor wherein a signal asserted at a first input terminal actuates in the alternate the first PMOS transistor and the first NMOS transistor simultaneously.

9. The apparatus according to claim 7, wherein said coupling circuit includes a second PMOS transistor coupled to a second NMOS transistor wherein a signal asserted at the second input terminal actuates in the alternate the second PMOS transistor and the second NMOS transistor simultaneously.

10. The apparatus according to claim 7, wherein the first input terminal, a gate of the first PMOS transistor, and a gate of the first NMOS transistor are coupled.

11. The apparatus according to claim 8, wherein the second input terminal, a gate of the second PMOS transistor, and a gate of the second NMOS transistor are coupled.

12. The apparatus according to claim 1, wherein said coupling circuit includes a series of a first and second PMOS transistors serially coupled and a first NMOS transistor coupled to the first PMOS transistor and the first input terminal, and a second NMOS transistor coupled to the second input terminal and to the second PMOS transistor.

13. An apparatus for providing a logic function comprising:
a coupling circuit;
a first circuit including a first input terminal for receiving a first input signal and a second input terminal for receiving a second input signal wherein said first circuit uses said coupling circuit for coupling said first and second input signals so as to generate an output signal wherein the output signal being a logic relationship between the first and second input signals;
a second circuit including a third input terminal for receiving a third input signal and a fourth input terminal for receiving a fourth input signal wherein said second circuit uses said coupling circuit for coupling said third and fourth input signals so as to generate an output signal wherein the output signal being a logic relationship between the third and fourth input signals; and
a third circuit using said coupling circuit for coupling the first and second circuits wherein said third circuit generates a first output signal and a second output signal having a logic relationship between the first, second, third and fourth inputs signals wherein the first output signal being an ORing output logic state and said second output signal being a NORing output state.

14. The apparatus according to claim 13, wherein said coupling circuit includes a NMOS transistor having a source coupled to the first input terminal and a gate coupled to the second input terminal.

15. The apparatus according to claim 13, wherein said coupling circuit includes a NMOS transistor having a source coupled to the second input terminal and a gate coupled to the first input terminal.

16. The apparatus according to claim 13, wherein said coupling circuit includes a first PMOS transistor serially coupled to a second PMOS transistor having a gate of said first PMOS transistor coupled to a first input terminal and a gate of the second PMOS transistor coupled to a second input terminal.

17. The apparatus according to claim 13, wherein said coupling circuit is at least a NMOS transistor having a source coupled to a first input terminal and a gate coupled to a second input terminal and a PMOS transistor having the source coupled to a second input terminal and the gate coupled to the first input terminal.

18. The apparatus according to claim 13, wherein said coupling circuit is at least a first PMOS transistor coupled to a first NMOS transistor wherein a signal asserted at a first input terminal actuates in the alternate the first PMOS transistor and the first NMOS transistor simultaneously.

19. The apparatus according to claim 16, wherein said coupling circuit includes at least a second PMOS transistor coupled to a second NMOS transistor wherein a signal asserted at the second input terminal actuates in the alternative the second PMOS transistor and the second NMOS transistor simultaneously.

20. The apparatus according to claim 16, wherein the first input terminal, a gate of the first PMOS transistor, and a gate of the first NMOS transistor are coupled.

21. The apparatus according to claim 19, wherein the second input terminal, a gate of the second PMOS transistor, and a gate of the second NMOS transistor are coupled.

22. The apparatus according to claim 13, wherein said coupling circuit is at least a series of a first and second PMOS transistors serially coupled and a first NMOS transistor coupled to the first PMOS transistor and the first input terminal and a second NMOS transistor coupled to the second input terminal and to the second PMOS transistor.

23. A method for providing a logic function, comprising:
receiving a first input signal for a first circuit at a first input terminal and a second input terminal for receiving a second input signal wherein said first circuit uses said coupling circuit for coupling said first and second input signals so as to generate an output signal wherein the output signal being a logic relationship between the first and second input signals;
receiving a second input signal for a second circuit having at least a third input terminal for receiving a third input signal and a fourth input terminal for receiving a fourth input signal wherein said second circuit uses said coupling circuit for coupling said third and fourth input signals so as to generate an output signal wherein the output signal being a logic relationship between the third and fourth input signals; and
comparing the outputs of the first and second circuits by using the third circuit by using said coupling circuit for coupling the first and second circuits wherein said third circuit generates a first output signal and a second output signal having a logic relationship between the first, second, third and fourth inputs signals wherein the first output signal being at an ORing output logic state and said second output signal being a NORing output state.

24. An apparatus including at least a coupling circuit for use in a logic function, comprising:
a first input terminal coupled to a first transistor of a first type and to a second transistor of a second type wherein said first transistor being coupled to said second transistor so as to receive a signal asserted at said first input terminal, and
a second input terminal coupled to a third transistor of a first type and to a fourth transistor of a second type wherein and said third transistor being coupled to said fourth transistor so as to receive a signal asserted at said second input terminal.

25. The apparatus according to claim 24, wherein the first transistor of a first type being a PMOS transistor.

26. The apparatus according to claim 24, wherein the second transistor of a second type being a NMOS transistor.

27. The apparatus according to claim 24, wherein the third transistor of a third type being a PMOS transistor.

28. The apparatus according to claim 24, wherein the fourth transistor of a fourth type being a NMOS transistor.

29. The apparatus according to claim 24, wherein the first transistor of a first type and the third transistor of a first type being serially coupled.

30. The apparatus according to claim 29, wherein a drain of the first transistor of a type being coupled to the source of the third transistor of a second type.

31. The apparatus according to claim 24, further comprising an output terminal coupled to a drain of the second transistor of a second type and to a drain of the fourth transistor of a second type so as to enable a receipt of a first and second output signal from the first and fourth transistors.

32. The apparatus according to claim 31, wherein the output terminal being coupled to a drain of the third transistor of a first type so as to enable a receipt of a third output signal from said third transistor.

33. A digital circuit for providing a logic function, comprising:
a first stage having two NMOS transistors and two PMOS transistors;
a second stage having two NMOS transistors and two PMOS transistors; and
a third stage having two NMOS transistors and two PMOS transistors;
wherein the third stage being coupled to the first and second stages receiving signals from the first and second stages to the third stage;
wherein said third stage outputting an EX NOR and an EX OR logic combination.

34. The digital circuit according to claim 33, further comprising:
said first stage serially connecting the two PMOS transistors and connecting in parallel the two NMOS transistors.

35. The digital circuit according to claim 34, further comprising:
said second stage serially connecting the two NMOS transistors and connecting in parallel the two NMOS transistors.

36. The digital circuit according to claim 35, further comprising:
said third stage serially connecting the two PMOS transistors and connecting in parallel the two PMOS transistors.
